(19) United States
(12) Patent Application Publication
(10) Pub. No.: US 2007/0264786 A1
(43) Pub. Date: Nov. 15, 2007

(54) METHOD OF MANUFACTURING METAL OXIDE SEMICONDUCTOR TRANSISTOR

(76) Inventors: Neng-Kuo Chen, Hsinchu City (TW); Shih-Fang Tzou, Hsinchu Hsien (TW); Teng-Chun Tsai, Hsinchu, (TW); Chien-Chung Huang, Taichung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,825

(22) Filed: May 11, 2006

(51) Int. Cl. H01L 21/336

(52) U.S. Cl. 438/308; 438/792; 438/682

(57) ABSTRACT

A method of manufacturing a metal oxide semiconductor (MOS) transistor is provided. The method includes first providing a substrate and forming an MOS transistor on the substrate. Then, a self-aligned metal silicidation process is performed. Afterwards, an infrared radiation (IR) treatment is performed on the substrate in order to repair damage therein. Because the damage in the substrate can be repaired by this method, the junction leakage of the MOS transistor can be efficiently reduced, and therefore the yield can be raised.

### BACKGROUND OF THE INVENTION

1. Field of Invention

The present invention relates to a method of manufacturing a semiconductor. More particularly, the present invention relates to a method of manufacturing a metal oxide semiconductor MOS to efficiently reduce junction leakage of the transistor.

2. Description of Related Art

With the approach of the deep sub-micrometer age of the semiconductor process, the improvement of drive current of NMOS and PMOS will greatly enhance the time-delay performance of transistor elements, so the process for 65 nm and below has become more and more important for improving the drive current of NMOS and PMOS.

For example, conventional research has been directed at low-k ILD material for raising the drive current. In recent years, research about the impact on the drive current of transistor elements caused by the film stress from shallow trench isolation (STI) oxide layers, SiN compressive or tensile structure of the poly-silicon cap, and the SiN contact etching stopper layer (SiN CESL) has been launched both domestically and abroad. As a result, the film stress from the STI oxide, SiN compressive or tensile structure of the poly-silicon cap, and the SiN CESL is deposited to a compressive or tensile stress. The higher the tensile strength of the film, the more the drive current of the NMOS is increased. Correspondingly, the more the film is compressed, the more the drive current of the PMOS is increased.

Moreover, it is also important to reduce the leakage current of transistor elements. Specialists both domestic and abroad tend to focus on how to repair the defects of transistors to reduce the leakage path. Therefore, how to raise the film stress of high tensile strength or high compressive strength SiN CESL effectively and meanwhile reduce the junction leakage of the transistor current has become an essential issue to improve transistor performance at present.

### SUMMARY OF THE INVENTION

An object of the present invention is to provide a method of manufacturing an MOS transistor to raise the drive current of the elements and reduce the junction leakage of the transistor.

Another object of the present invention is to provide a method of manufacturing an MOS transistor to repair the damage to the chip surface, thus greatly reducing the junction leakage of the transistor and thereby raising the yield.

The present invention provides a method of manufacturing an MOS transistor, which includes first providing a substrate and forming an MOS transistor on the substrate. Then, a CESL is deposited on the substrate to cover the MOS transistor. Afterwards, an UV curing process is performed on the CESL and meanwhile an infrared radiation (IR) treatment is performed on the substrate.

In the method of manufacturing an MOS transistor according to an embodiment of the present invention, a power density of the IR treatment is in the range of 0.7-14.1 W/cm², and preferably 1.4-7.0 W/cm².

In the method of manufacturing an MOS transistor according to an embodiment of the present invention, the temperature of the UV curing process is between 150° C. and 700° C. The time period thereof is between 10 seconds and 60 minutes. The wavelength of the UV light is between 100 nm and 400 nm.

The method of manufacturing an MOS transistor according to an embodiment of the present invention further comprises a step of performing a self-aligned metal silicidation process after forming the MOS transistor on the substrate, such that a metal salicide layer is formed on the surface of gate, source, and drain of the MOS transistor.

In the method of manufacturing an MOS transistor according to an embodiment of the present invention, the method for depositing the above CESL on the substrate includes a chemical vapor deposition process for depositing a SiN layer on the substrate. The CESL is a compressive dielectric film or a tensile dielectric film.

The present invention provides another method of forming an MOS transistor, which includes first providing a substrate and forming an MOS transistor on the substrate. Then, a self-aligned metal silicidation process is performed. Afterwards, an IR treatment is performed on the substrate to repair the damage of the substrate.

In the method of manufacturing an MOS transistor according to another embodiment of the present invention, the power density of the IR treatment is within the range of 0.7-14.1 W/cm², and preferably 1.4-7.0 W/cm².

In the method of manufacturing an MOS transistor according to another embodiment of the present invention, after the IR treatment is performed on the substrate, a CESL is deposited on the substrate to cover the MOS transistor. The method of depositing the CESL on the substrate includes a chemical vapor deposition process for depositing a SiN layer on the substrate.

In the method of manufacturing an MOS transistor according to another embodiment of the present invention, if the MOS transistor is a PMOS, the CESL is a compressive dielectric film.

In the method of manufacturing an MOS transistor according to another embodiment of the present invention, if the MOS transistor is an NMOS, the CESL is a tensile dielectric film.

Since an IR treatment is added when the UV curing process is performed on the CESL for improving the element stress according to the present invention, an effect of heat treatment on the substrate surface is achieved, such that the damage having resulted from the implantation process is repaired. Furthermore, as an IR treatment is performed on the chip surface after the self-aligned metal silicidation process according to the present invention, not only is the purpose of repairing the substrate damage achieved, but also the NiSi process is not affected because the temperature is no more than 400° C. Therefore, the junction leakage of the MOS transistor can be greatly reduced, and thus the yield can be raised.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A to 1D are schematic sectional views of the process of manufacturing an MOS transistor according to the first embodiment of the present invention.

FIGS. 2A to 2D are schematic sectional views of the process of manufacturing an MOS transistor according to the second embodiment of the present invention.

FIG. 3 is a comparison view of the junction leakages of an NMOS obtained according to the method of the present invention and a conventional NMOS not going through IR treatment.

FIG. 4 is a comparison view of the junction leakages of a PMOS obtained according to the method of the present invention and a conventional PMOS not going through IR treatment.

FIG. 5 is a comparison view of the JDs of an NMOS obtained according to the method of the present invention and a conventional NMOS without going through the UV curing process and the IR treatment.

### DESCRIPTION OF EMBODIMENTS

The concept of the present invention involves using the IR, which is avoided to be used in conventional arts, to process a substrate with an MOS transistor formed thereon, thus greatly reducing the junction leakage of the transistor and raising the yield. The present invention will be illustrated by the following exemplary embodiments, but is not limited thereto.

### First Embodiment

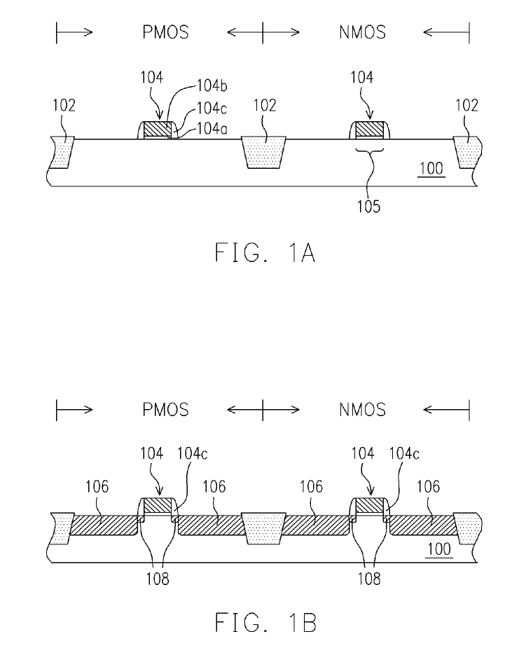

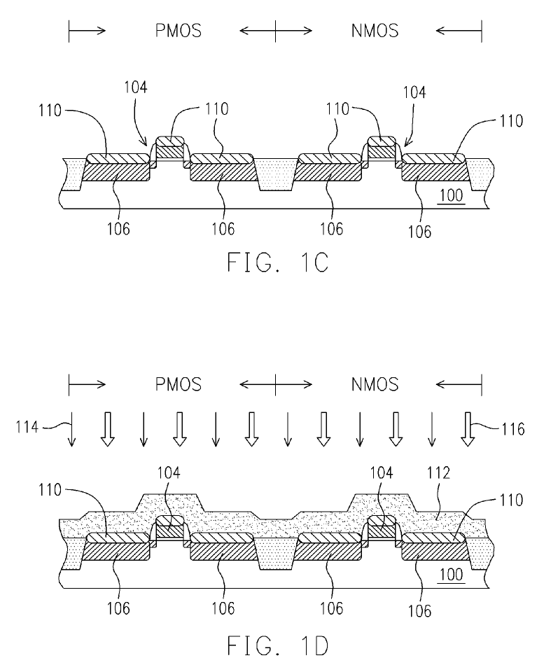

FIGS. 1A to 1D are schematic sectional views of the process of manufacturing an MOS transistor according to the first embodiment of the present invention.

Referring to FIG. 1A, a substrate 100 is provided first. It is assumed that the substrate 100 is separated into PMOS regions and NMOS regions by several isolation structures 102. Then, an MOS transistor is formed on the substrate 100. The substrate 100 is, for example, a silicon based structure. The isolation structure 102 for separating the PMOS regions and the NMOS regions is generally a shallow trench isolation (STI) structure made of, for example, silicon oxide. The method of forming the MOS transistor varies in accordance with different element sizes and different processes. For example, a gate structure 104, which includes at least a gate dielectric layer 104a, a gate 104b, and a spacer 104c, is formed on the substrate 100 between the isolation structures 102. The material of the gate dielectric layer 104a is, for example, silicon oxide. The material of the gate 104b is, for example, doped poly-silicon. The material of the spacer 104c is, for example, silicon oxide or silicon nitride. Furthermore, the substrate 100 below the gate structure 104 serves as a channel region 105 of the MOSFET (metal oxide semiconductor FET). In addition, the gate structure 104 further includes other means which can be deduced by those skilled in the art based on conventional arts, and thus the details will not be described herein.

And then, referring to FIG. 1B, a source and drain 106 is respectively formed on the substrate 100 on both sides of the gate structure 104, and the forming method is a conventional ion-implantation process. Or, with the approach of the deep sub-micrometer age of the semiconductor process (such as, 65 nm below), the method, for example, a selective epitaxial deposition, can be used to grow the source and drain 106 only on the silicon based substrate 100, rather than on the silicon oxide or silicon nitride. The selective epitaxial deposition includes vapor phase epitaxy, which comprises reduced pressure chemical vapor deposition epitaxial deposition, atmosphere chemical vapor deposition epitaxy, and ultra high vacuum chemical vapor deposition epitaxy. Furthermore, a source and drain extension region 108 can be formed below the spacer 104c in the gate structure 104 before the source and drain 106 is formed, so as to alleviate a short channel effect. The material of the source and drain extension layer 108 is, for example, mono-crystalline silicon with dopants, epitaxial silicon, SiGe or SiC. The method for forming the source and drain extension layer 108 is similar as that of the source and drain 106, such as a conventional ion-implantation process or a selective epitaxial deposition. Also, an in-situ doping or ex-situ doping can be used during the forming period thereof to implant the dopants into the source and drain extension layer 108 and the source and drain 106.

Subsequently, the step of FIG. 1C is performed to perform a self-aligned metal silicidation process to form a metal salicide layer 110 on the surface of the gate 104b in the gate structure 104 and the surface of source and drain 106. The material of the above metal salicide layer 110 is selected from a group consisting of titanium silicide, nickel silicide, cobalt silicide, platinum silicide, tungsten silicide, tantalum silicide, and molybdenum silicide. Additionally, the metal salicide layer 110 formed on the surface of the gate 104b and the metal salicide layer 110 formed on the surface of the source and drain 106 can be made of different material, and the manufacturing flow thereof can also be different accordingly. For example, the surface of the gate 104b is covered with a cap layer at first, which will not be removed until the metal salicide layer 110 is formed on the surface of the source and drain 106. Then, the metal salicide layer 110 is formed on the surface of the gate 104b.

After that, referring to FIG. 1D, a CESL 112 is deposited on the substrate 100 to cover the aforementioned MOS transistor 104. The CESL 112 is deposited by, for example, using a chemical vapor deposition process to deposit a SiN layer on the substrate. The CESL 112 can be a compressive dielectric film or a tensile dielectric film. Then, an UV curing process 114 is performed on the CESL 112, and meanwhile an IR treatment 116 is performed on the substrate 100. The temperature of the UV curing process is between 150° C. and 700° C. The time period thereof is between 10 seconds and 60 minutes. The wavelength of the UV light is, for example, within the range of 100 nm-400 nm. The power density of the aforementioned IR treatment 116 is, for example, within the range of 0.7-14.1 W/cm², and preferably 1.4-7.0 W/cm².

As an IR treatment is added at the same time when performing the UV curing process, an effect of repairing the damage in the substrate can be achieved, thereby improving the performance of the MOS transistor as well as reducing the junction leakage of the transistor efficiently. For example, when the MOS transistor is an NMOS in the first embodiment, the IR treatment 116 is performed at the same time when performing the UV curing process 114 to strengthening the tensile stress of the tensile dielectric film until more than 1.8 GPa, after a tensile dielectric film (such as a SiN layer) is coated on the substrate, such that a maximum NMOS drive current can be achieved. Furthermore, as an IR treatment on the substrate is added, the damage having resulted from the implantation process is repaired, and the junction leakage of the NMOS is greatly reduced, thereby raising the yield.

### Second Embodiment

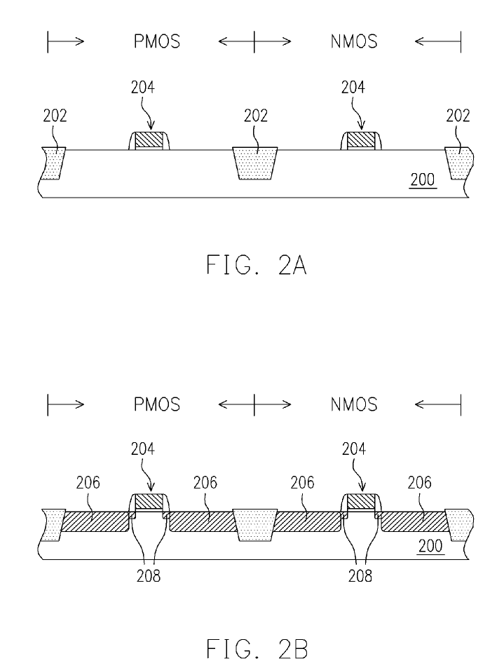

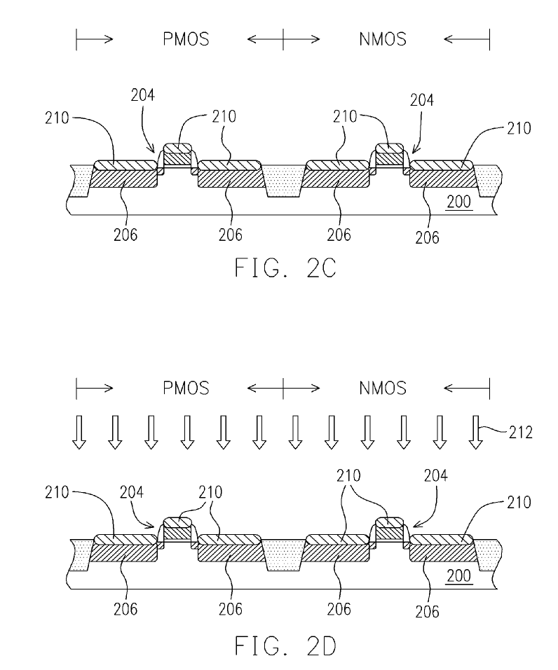

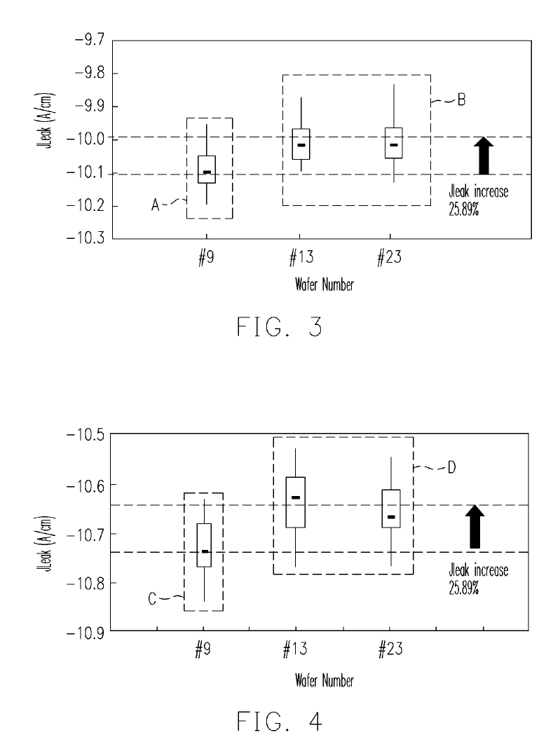

FIGS. 2A to 2D are schematic sectional views of the process of manufacturing an MOS transistor according to the second embodiment of the present invention.

Referring to FIG. 2A, a substrate 200 is provided first. It is assumed that the substrate 200 is separated into PMOS regions and NMOS regions by several isolation structures 202. Then, an MOS transistor is formed on the substrate 200. The method of forming the MOS transistor varies in accordance with different element sizes and different processes. For example, a gate structure 204, which includes at least a gate dielectric layer, a gate, and a spacer, is formed on the substrate 200 between the isolation structures 202. The detailed structure thereof can be deduced with reference to the above embodiment or can be deduced from the process or structure by those skilled in the art based on conventional arts, and thus will not be described in detail herein.

And then, referring to FIG. 2B, a source and drain 206 is respectively formed on the substrate 200 on both sides of gate structure 204, and the forming method thereof is a conventional ion-implantation process or a selective epitaxial deposition as those described in the above embodiment. The selective epitaxial deposition is, for example, vapor phase epitaxy, which comprises reduced pressure chemical vapor deposition epitaxial deposition, atmosphere chemical vapor deposition epitaxy, and ultra high vacuum chemical vapor deposition epitaxy. Furthermore, a so-called source and drain extension region 208 can be selectively formed below the spacer in the gate structure 204 before the source and drain 206 is formed, so as to alleviate a short channel effect. The material and the manufacturing method of the source and drain extension layer 208 are the same as those described in the above embodiment.

Subsequently, referring to FIG. 2C, a self-aligned metal silicidation process is performed to form a metal salicide layer 210 on the gate surface of the gate structure 204 and the surface of the source and drain 206. The self-aligned metal silicidation process involves, for example, depositing a metal layer (not shown) on the substrate 200 to cover the gate surface of the gate structure 204 and the surface of the source and drain 206. Then, a silicidation reaction occurs between the aforementioned metal layer and the gate structure 204 and the source and drain 206 containing silicon. Afterwards, the un-reacted metal layer is removed. The material of the metal salicide layer 210 is selected from a group consisting of titanium silicide, nickel silicide, cobalt silicide, platinum silicide, tungsten silicide, tantalum silicide, and molybdenum silicide. Additionally, the metal salicide layer 210 formed on the surface of the gate structure 204 and the metal salicide layer 210 formed on the surface of the source and drain 206 can be made of same or different material, and the manufacturing flow thereof can also be different accordingly. For example, the surface of the gate structure 204 is covered with a cap layer at first, which will not be removed until the metal salicide layer 210 is formed on the surface of the source and drain 206. Then, another metal salicide layer 210 is formed on the surface of the gate structure 204.

After that, referring to FIG. 2D, after the self-aligned metal silicidation process, an IR treatment 212 is performed on the substrate 200 to repair the damage in the substrate 200. The power density of the IR treatment 212 is, for example, within the range of 0.7-14.1 W/cm², and preferably 1.4-7.0 W/cm². Then, a CESL is deposited on the substrate 200 to cover the MOS transistor 204. The method of depositing the CESL on the substrate includes a chemical vapor deposition process to deposit a SiN layer on the substrate 200. Moreover, if the aforementioned MOS transistor 204 is a PMOS, the CESL is a compressive dielectric film. Otherwise, if the aforementioned MOS transistor is an NMOS, the CESL is a tensile dielectric film, such that the structure stress of the PMOS regions and the NMOS regions can be improved.

As the IR treatment can be performed at any stage after the self-aligned metal silicidation process in the second embodiment, the damage in the substrate can be repaired, thereby effectively reducing the junction leakage of the transistor. Additionally, when the self-aligned metal silicidation process proceeds to the nickel silicide process, the method of the second embodiment will not affect the nickel silicidation process as the temperature in the method is generally no more than 400° C.

The electrical performance of the MOS transistor obtained according to the manufacturing method of the present invention and that of the conventional MOS transistor not going through IR treatment are compared as follows.

Referring to FIGS. 3 and 4, these two figures illustrate the comparison views of the junction leakages of the NMOS and PMOS obtained according to the manufacturing method of the present invention and the conventional NMOS and PMOS not going through IR treatment, respectively. The block A and block C are obtained according to the method of the present invention in a manner described in the first embodiment. The power density of the IR treatment is about 5.66 W/cm². It can be known from FIGS. 3 and 4 that the junction leakage of the conventional NMOS (block B) and PMOS (block D) not going through IR treatment is 25.89% higher than that of the NMOS (block A) and PMOS (block C) according to the present invention. Therefore, the junction leakage of the MOS transistor can be effectively reduced according to the present invention, and thereby the yield is raised.

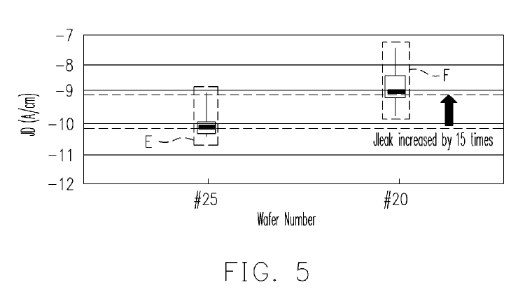

Additionally, FIG. 5 is a comparison view of the JDs of the NMOS according to the method of the present invention and the NMOS without going through the UV curing process and the IR treatment. It can be known from FIG. 5 that the junction leakage of the NMOS without going through the UV curing process and the IR treatment is 15 times that of the block E according to the present invention.

In view of the above, the IR, which is avoided to be used in conventional arts, is employed in the present invention to process the substrate, so as to repair the damage in the substrate having resulted from the implantation process or other process, and thus greatly reducing the junction leakage of the transistor. Furthermore, the IR treatment can be used in conjunction with the UV curing process, such that the tensile stress of the SiN can be increased to more than 1.4 GPa, and thus the drive current of the NMOS is increased by more than 12% approximately.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of manufacturing a metal oxide semiconductor (MOS) transistor, comprising:
providing a substrate;
forming an MOS transistor on the substrate;
depositing a contact etching stopper layer (CESL) on the substrate to cover the MOS transistor; and
performing an UV curing process to the CESL and performing an infrared radiation (IR) treatment to the substrate at the same time.

2. The method of manufacturing an MOS transistor as claimed in claim 1, wherein a power density of the IR treatment is within the range of 0.7-14.1 W/cm².

3. The method of manufacturing an MOS transistor as claimed in claim 2, wherein the power density of the IR treatment is within the range of 1.4-7.0 W/cm².

4. The method of manufacturing an MOS transistor as claimed in claim 1, wherein the temperature of the UV curing process is between 150° C. and 700° C.

5. The method of manufacturing an MOS transistor as claimed in claim 1, wherein a time period of the UV curing process is between 10 seconds and 60 minutes.

6. The method of manufacturing an MOS transistor as claimed in claim 1, wherein a wavelength of the UV light in the UV curing process is between 100 nm and 400 nm.

7. The method of manufacturing an MOS transistor as claimed in claim 1, further comprising performing a self-aligned metal silicidation process after forming the MOS transistor on the substrate.

8. The method of manufacturing an MOS transistor as claimed in claim 1, wherein a process for depositing the above CESL on the substrate includes a chemical vapor deposition process to deposit a silicon nitride layer on the substrate.

9. The method of manufacturing an MOS transistor as claimed in claim 1, wherein the CESL includes a compressive dielectric film or a tensile dielectric film.

10. A method of manufacturing a metal oxide semiconductor (MOS) transistor, comprising:
providing a substrate;
forming an MOS transistor on the substrate;
performing a self-aligned metal silicidation process; and
performing an infrared radiation (IR) treatment to the substrate in order to repair damage in the substrate.

11. The method of manufacturing an MOS transistor as claimed in claim 10, wherein the power density of the IR treatment is within the range of 0.7-14.1 W/cm².

12. The method of manufacturing an MOS transistor as claimed in claim 11, wherein the power density of the IR treatment is within the range of 1.4-7.0 W/cm².

13. The method of manufacturing an MOS transistor as claimed in claim 10, further comprising depositing a CESL on the substrate to cover the MOS transistor after the IR treatment is performed on the substrate.

14. The method of manufacturing an MOS transistor as claimed in claim 13, wherein the process of depositing the CESL on the substrate includes a chemical vapor deposition process to deposit a silicon nitride layer on the substrate.

15. The method of manufacturing an MOS transistor as claimed in claim 13, wherein when the MOS transistor is a PMOS, the CESL is a compressive dielectric film.

16. The method of manufacturing an MOS transistor as claimed in claim 13, wherein when the MOS transistor is an NMOS, the CESL is a tensile dielectric film.
